(19) United States
(12) Patent Application Publication
(10) Pub. No.: US 2026/0072591 A1
(43) Pub. Date: Mar. 12, 2026

(54) MEMORY SYSTEM FOR CONTROLLING READ AND WRITE OPERATIONS BASED ON PRIORITIES AND OPERATION METHOD THEREOF

(71) Applicant: SK hynix Inc., Gyeonggi-do (KR)

(72) Inventor: Du Hyun KIM, Gyeonggi-do (KR)

(21) Appl. No.: 19/034,558

(22) Filed: Jan. 23, 2025

(30) Foreign Application Priority Data
Sep. 10, 2024 (KR) 10-2024-0123214

(51) Int. Cl. G06F 3/06

(52) U.S. Cl. CPC G06F 3/061; G06F 3/0631; G06F 3/0659; G06F 3/0673

(57) ABSTRACT

A memory system includes at least one memory device and a controller. The controller is coupled to the at least one memory device. The controller is configured to change a processing order of next data input/output (I/O) requests, input after plural data I/O requests, based on whether preset internal resources are allocated for processing the plural data I/O requests.

### CROSS-REFERENCE TO RELATED APPLICATIONS

This patent application claims the benefit of priority under 35 U.S.C. § 119(a) to Korean Patent Application No. 10-2024-0123214, filed on Sep. 10, 2024, the entire disclosure of which is incorporated herein by reference.

### TECHNICAL FIELD

Embodiments of the present disclosure described herein relate to a memory system, and more particularly, to a memory system controlling read and write operations based on priorities, and an operation method of the memory system.

### BACKGROUND

Computing systems are increasing in computational volume and data processing speed in response to user needs. A memory system in a computing system performs an operation of inputting and outputting data in response to a request from an external device such as a host. The memory system can receive a data input/output request from at least one external device. The memory system can assign a priority to the data input/output request or an operation or a task corresponding to the data input/output request in order to efficiently manage and perform the data input/output request. In addition, when at least one external device assigns a priority to the data input/output request, the memory system can handle or process an operation based on the priority assigned to the data input/output request.

### BRIEF DESCRIPTION OF THE DRAWINGS

The description herein makes reference to the accompanying drawings wherein like reference numerals refer to like parts throughout the figures.

FIG. 1 illustrates a memory system according to an embodiment of the present disclosure.

FIG. 2 illustrates a first operation performed in a memory system according to an embodiment of the present disclosure.

FIG. 3 illustrates a method for allocating resources based on priorities in a memory system according to an embodiment of the present disclosure.

FIG. 4 illustrates a second operation performed in a memory system according to an embodiment of the present disclosure.

FIG. 5 illustrates a third operation performed in a memory system according to an embodiment of the present disclosure.

FIG. 6 illustrates a data processing apparatus according to an embodiment of the present disclosure.

FIG. 7 illustrates another data processing apparatus according to an embodiment of the present disclosure.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, circuits, a memory storing program instructions executable to implement the operation, etc. Additionally, “configured to” can include a generic structure, e.g., generic circuitry, that is manipulated by software and/or firmware, e.g., an FPGA or a general-purpose processor executing software to operate in a manner that is capable of performing the task(s) at issue. “Configured to” may also include adapting a manufacturing process, e.g., a semiconductor fabrication facility, to fabricate devices, e.g., integrated circuits that are adapted to implement or perform one or more tasks.

As used in this disclosure, the term ‘machine,’ ‘circuitry’ or ‘logic’ refers to all of the following: (a) hardware-only circuit implementations such as implementations in only analog and/or digital circuitry and (b) combinations of circuits and software and/or firmware, such as (as applicable): (i) to a combination of processor(s) or (ii) to portions of processor(s)/software including digital signal processor(s), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘machine,’ ‘circuitry’ or ‘logic’ applies to all uses of this term in this application, including in any claims. As a further example, as used in this application, the term ‘machine’, ‘circuitry’ or ‘logic’ also covers an implementation of merely a processor or multiple processors or a portion of a processor and its (or their) accompanying software and/or firmware. The term ‘machine’, ‘circuitry’ or ‘logic’ also covers, for example, and if applicable to a particular claim element, an integrated circuit for a storage device.

As used herein, the terms ‘first’, ‘second’, ‘third’, and so on are used as labels for nouns that they precede, and do not imply any type of ordering, e.g., spatial, temporal, logical, etc. The terms ‘first’ and ‘second’ do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term ‘based on’ is used to describe one or more factors that affect a determination. This term does not foreclose additional factors that may affect determination. The determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

An embodiment of the present disclosure can provide scheduling that dynamically changes a throughput corresponding to a priority based on a number of data input/output requests, classified and buffered according to the priority, to improve performance of a computing system including a host and a memory system.

In addition, an embodiment of the present disclosure can provide a device and a method capable of improving the data input/output performance and operational safety in a memory system by dynamically changing throughput of read and write operations based on an operating environment and an operational state of the memory system.

An embodiment of the present disclosure provides a memory system including at least one memory device; and a controller coupled to the at least one memory device and configured to change a processing order of next data input/output (I/O) requests, input after plural data I/O requests, based on whether preset internal resources are allocated for processing the plural data I/O requests.

The controller can be configured to: determine the processing order of the next data I/O requests based on an allocation ratio of the internal resources according to priorities when the preset internal resources are allocated for processing the plural data I/O requests; and determine the processing order of the next data I/O requests in a round robin manner with the allocation ratio of the internal resources when at least some of the preset internal resources is not allocated.

The controller can be further configured to compare a number of the plural data I/O requests with a first reference value corresponding to the internal resources to determine whether the preset internal resources are allocated.

The internal resources can include a read buffer and a write buffer included in, or operatively engaged with, the controller. Each of the read buffer and the write buffer can be configured to store a maximum number of the plural data I/O requests, the maximum number corresponding to the first reference value.

The controller can be configured to: receive read data from the at least one memory device or receive a completion signal for write data from the at least one memory device in response to the data I/O requests stored in each of the read buffer and the write buffer; and remove a first data input/output request from the read buffer or the write buffer when a response to the first data input/output request corresponding to the read data or the completion signal is generated.

The priorities can include a first priority and a second priority lower than the first priority. The controller can be configured to store, in the read buffer or the write buffer, at least one first data I/O request of the first priority and at least one second data input/output request of the second priority. The first number of the at least one first I/O request and the second number of the at least one second I/O request, which are stored in the read buffer or the write buffer, can be determined based on the allocation ratio.

The first number can be equal to or less than three times the second number.

The controller can be configured to: compare the first number with a second reference value based on the priorities when the preset internal resources are allocated; and determine priorities for the next data I/O requests to be stored in the read buffer or the write buffer based on a comparison result.

The second reference value can be determined based on the allocation ratio.

The second reference value can be ¾ of the first reference value.

In another embodiment, a controller can be configured to allocate internal resources for processing plural data input/output (I/O) requests to be performed within at least one memory device. The controller can be configured to: determine a processing order of the next data I/O requests based on an allocation ratio of the internal resources and priorities when preset the internal resources are allocated for processing the plural data I/O requests; and determine the processing order of the next data I/O requests in a round robin manner with the allocation ratio when at least some of the preset internal resources is not allocated for processing the plural data I/O requests.

The controller can be further configured to compare a number of the plural data I/O requests with a first reference value corresponding to the internal resources to determine whether the preset internal resources are allocated.

The internal resources can include a read buffer and a write buffer included in, or operatively engaged with, the controller. Each of the read buffer and the write buffer can be configured to store a maximum number of the plural data I/O requests, the maximum number corresponding to the first reference value.

The controller can be configured to: receive read data from the at least one memory device or receive a completion signal for write data from the at least one memory device in response to the data I/O requests stored in each of the read buffer and the write buffer; and remove a first data input/output request from the read buffer or the write buffer when a response to the first data input/output request corresponding to the read data or the completion signal is generated.

The priorities can include a first priority and a second priority lower than the first priority. The controller can be configured to store, in the read buffer or the write buffer, at least one first data I/O request of the first priority and at least one second data input/output request of the second priority. The first number of the at least one first I/O request and the second number of the at least one second I/O request, which are stored in the read buffer or the write buffer, can be determined based on the allocation ratio.

The controller can be configured to: compare the first number with a second reference value based on priorities when the preset internal resources are allocated; and determine priorities for the next data I/O requests to be stored in the read buffer or the write buffer based on a comparison result.

In another embodiment, a method for operating a memory system can include assigning different priorities to plural data input/output (I/O) requests based on properties of the plural data I/O requests to be performed within at least one memory device; allocating internal resources for processing the plural data I/O requests based on an allocation ratio corresponding to the priorities; and changing a processing order of next data I/O requests input after the plural data I/O requests, based on whether preset internal resources are allocated.

The changing the processing order can include determining a processing order of the next data I/O requests based on an allocation ratio of the internal resources and priorities when the preset the internal resources are allocated for processing the plural data I/O requests; and determining the processing order of the next data I/O requests in a round robin manner with the allocation ratio when at least some of the preset internal resources is not allocated for processing the plural data I/O requests.

The method can further comprises comparing a number of the plural data I/O requests with a first reference corresponding to the internal resources to determine whether the preset internal resources are allocated.

The internal resources can include a read buffer and a write buffer included in, or operatively engaged with, the controller. Each of the read buffer and the write buffer can be configured to store a maximum number of the plural data I/O requests, the maximum number corresponding to the first reference value.

These and other features and advantages of the invention will become apparent from the detailed description and the accompanying drawings of embodiments of the present disclosure.

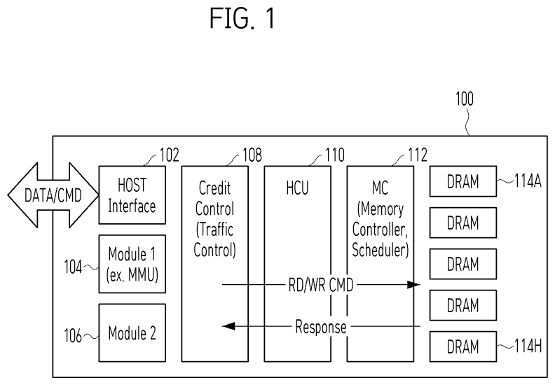

Embodiments will now be described with reference to the accompanying drawings, wherein like numbers reference like elements. FIG. 1 illustrates a memory system 100 according to an embodiment of the present disclosure.

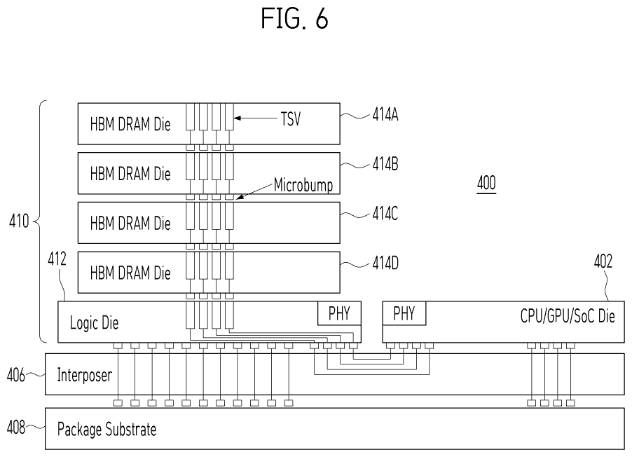

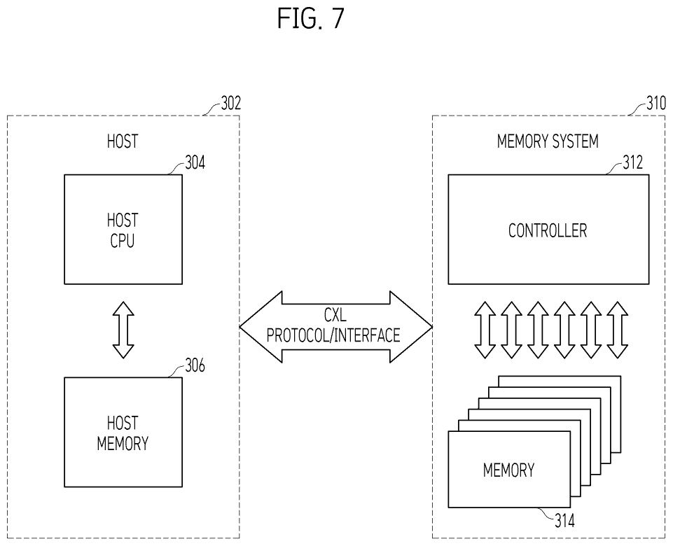

Referring to FIG. 1, the memory system 100 can include a host interface 102 for performing data communication with an external device (e.g., a host). The memory system 100 can be coupled or connected to an external device through a preset interface or a preset protocol to perform data communication. The memory system 100 can receive a data input/output (I/O) request (e.g., a read or write command RD/WR CMD), sometimes along with data, from the external device through the host interface 102 and output a response, sometimes including data, corresponding to the received data I/O request. A data input/output (I/O) apparatus including the memory system 100 and the external device will be described later with reference to FIGS. 6 and 7.

The memory system 100 can include a plurality of memory devices 114A to 114H. In FIG. 1, the plurality of memory devices 114A to 114H are described as including DRAM memory cells as an example. But the configuration of the plurality of memory devices 114A to 114H can vary depending on an embodiment. For example, each of the plurality of memory devices 114A to 114H can include a different type of volatile memory cells (e.g., SRAM). In addition, depending on an embodiment, the plurality of memory devices 114A to 114H can include a data storage area or region with different-types of memory cells (e.g., volatile memory cells or non-volatile memory cells). For example, some of the plurality of memory devices 114A to 114H can include DRAM memory cells, and others can include NAND memory cells.

The memory system 100 can include a hazard control unit (HCU) 110. The hazard control unit 110 can play a role in detecting and resolving various types of hazards occurring within the memory system 100. Various components related to the hazard control unit 110 can interact for efficient operation of the controller of the memory system 100. The hazard control unit 110 is a component configured to detect and resolve various types of hazards that may occur during pipeline processing in a controller of the memory system 100. The pipeline processing is a technique for improving a processing speed by dividing requests or commands into plural stages and processing the requests or the commands simultaneously. But, data hazards, control hazards, structural hazards, etc. could occur during pipeline processing.

The data hazards can occur when data required for an instruction is not yet prepared by a previous instruction while the instruction is being executed. To resolve this situation, the hazard control unit 110 can delay the execution of the current instruction until the required data is prepared or can directly transfer the required data through a data forwarding technique.

The control hazards can occur when it is needed to determine which instruction to execute next before a result of a branch instruction (e.g., jump, branch, etc.) is determined. To solve this situation, the hazard control unit 110 can use a branch prediction technique to predict the outcome of a branch. If the branch prediction is incorrect, the hazard control unit 110 can cancel incorrectly executed instructions and execute instructions on a correct path.

The structural hazards can occur when hardware resources in the pipeline configured in the controller of the memory system 100 are insufficient but multiple instructions attempt to use insufficient resources at the same time. For example, multiple instructions could be transmitted to an instruction input/output device that can execute only one instruction at a time. To solve this situation, the hazard control unit 110 can delay the execution of the instruction until needed resources become available for the corresponding instruction.

The memory system 100 can include a memory management unit (MMU) 104. The memory management unit 104 can be configured as a module (Module 1). According to an embodiment, the memory management unit 104 can perform a role of converting a virtual memory address into a physical memory address. The memory management unit (MMU) 104 can provide an independent virtual memory space for each process to enable memory protection and efficient memory use. The memory management unit (MMU) 104 can use a cache mechanism such as a Translation Lookaside Buffer (TLB) to reduce memory access delay that may occur during the address translation process. The hazard control unit 110 can reduce the impact of the memory access delay that occurs in the memory management unit 104 on the pipeline within the memory system 100.

The memory system 100 can include a memory controller (MC) 112.

The memory controller 112 can transmit data I/O commands (e.g., read commands, write commands, etc.) input from the hazard control unit 110 to the plurality of memory devices (DRAMs) 114A to 114H and receive responses (e.g., read data, write completion, etc.) to the data I/O commands from the plurality of memory devices 114A to 114H. The memory controller 112 can transmit responses (e.g., read data, write completion, etc.), which are generated based on information received from the plurality of memory devices 114A to 114H, to the hazard control unit 110. The hazard control unit 110 can generate a response output to an external device based on data or information transmitted from the memory controller 112.

The memory system 100 can include a credit controller 108.

According to an embodiment, the credit controller 108 can assign different priorities to plural data I/O requests input from an external device and plural data input/output commands generated through background operations performed within the memory system 100. For example, the credit controller 108 can assign a first priority to plural data I/O requests input from an external device and assign a second priority, which is lower than the first priority, to plural data input/output commands generated through background operations. Further, the credit controller 108 can determine or adjust sizes of entries processed based on the different priorities. For example, the credit controller 108 can determine a size of first entries with the first priority and a size of second entries with the second priority, when the first entries and the second entries are stored in a buffer. The hazard control unit 110 can prioritize processing of the data input/output requests with the first priority over that of the data input/output commands with the second priority.

According to an embodiment, an external device connected to the memory system 100 can transmit priorities along with the data input/output requests. When a priority is assigned to a data input/output request input from the external device, the credit controller 108 in the memory system 100 can determine a processing order of data input/output requests based on priorities assigned to the data input/output requests.

If the credit controller 108 assigns different priorities to data input/output requests, the hazard control unit 110 can determine the processing order of the data I/O requests based on the priorities. For at least one data I/O request with a high priority, the hazard control unit 110 can allocate more or faster internal resources than another request, to adjust or change the processing order of the data I/O requests to be performed faster than another request within the plurality of memory devices 114A to 114H. Conversely, for at least one data input/output command with a low priority, the hazard control unit 110 can allocate fewer or slower internal resources than another request, to adjust or change the processing order of the data input/output command to be performed slower than another request in the plurality of memory devices 114A to 114H.

According to an embodiment, the memory system 100 can further include at least one component (e.g., Module 2) 106 in addition to the above-described components. For example, the component 106 can include a module that can check and correct an error in write data or read data, a module that can encrypt or decrypt data, write data or read data for security, a module that can adjust a processing rate based on power supply or temperature, etc. The component 106 can vary depending on the operating performance of the memory system 100.

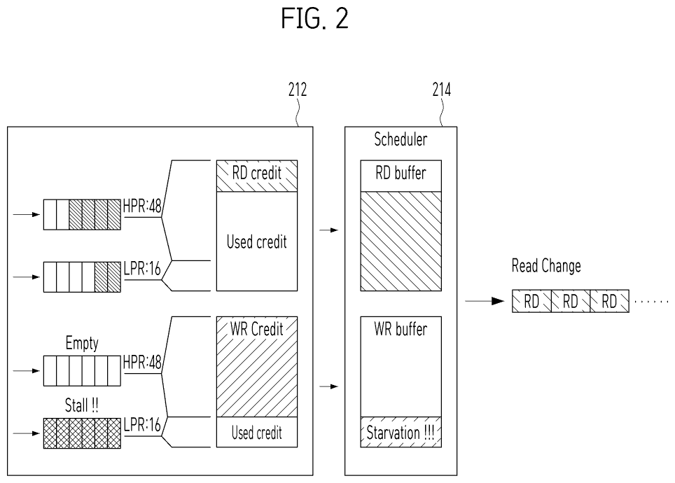

FIG. 2 illustrates a first operation performed in a memory system according to an embodiment of the present disclosure.

Referring to FIG. 2, the memory system can include a priority processor 212 and a scheduler 214. The priority processor 212 can allocate internal resources to process or handle data input/output requests based on priorities. The scheduler 214 can process data I/O requests to which internal resources are allocated. According to an embodiment, the priority processor 212 and the scheduler 214 can be included in the credit controller 108 or the hazard control unit (HCU) 110 described in FIG. 1.

According to an embodiment, the memory system can include a read buffer used for processing read requests and a write buffer used for processing write requests. According to another embodiment, the read requests and the write requests can be processed through a single buffer. In this embodiment, frequent changes in an operation mode (e.g., from a read mode to a write mode, or vice versa) can occur. Frequent changes in the operation mode can lower the throughput of the memory system. To solve this issue, the memory system can separate the read buffer configured to process the read requests and the write buffer configured to process the write requests and, then, individually process the read requests and the write requests through separate processing paths or tasks (e.g., via distinguishable or separate pipelines).

Sizes of the read buffer and the write buffer can have a fixed size corresponding to the internal resources and internal configuration of the memory system. But, according to an embodiment, the sizes of the read buffer and the write buffer could be changed corresponding to the operating environment of the memory system. In addition, the sizes of the read buffer and the write buffer could be different from each other, according to an embodiment. Depending on the operating environment of the memory system, when there are many read requests input from the external device, the memory system can use or allocate more internal resources to process read requests than those to process write requests. Conversely, when there are many write requests input from the external device, the memory system can use or allocate more internal resources to process write requests than those to process read requests.

For convenience of description, FIG. 2 describes an example in which each of the read buffer and the write buffer is configured to process 64 read or write requests. In addition, the allocation ratio can be determined corresponding to different priorities. For example, the sizes of the read buffer or the write buffer can be determined based on the first reference value set corresponding to the internal resources included in the memory system. Referring to FIG. 2, the first reference value is 64 (e.g., the number of allocatable credits).

Among different priorities, the memory system can allocate or assign more internal resources to a data I/O request with a higher priority than that with a lower priority. This difference can be determined by an allocation ratio. Depending on the embodiment, the allocation ratio can vary depending on durability configuration of the memory system, data input/output performance, preset policies shared with the external device such as a host, etc. In FIG. 2, the allocation ratio for two different priorities is described as 3:1. For example, 48 entries out of 64 entries in the read buffer are allocated or used for read requests with a first priority HPR, and the remaining 16 entries can be allocated or used for read requests with a second priority LPR lower than the first priority HPR. Similarly, 48 entries out of 64 entries in the write buffer are allocated or used for write requests with the first priority HPR, and the remaining 16 are allocated or used for write requests with the second priority LPR lower than the first priority HPR.

The data I/O requests input to the priority processor 212 can be classified based on a type of the data I/O requests and priorities assigned to the data I/O requests. For example, the priority processor 212 can classify the data I/O requests into a read request assigned to the first priority HPR among read requests, a read request assigned to the second priority LPR among the read commands, a write request assigned to the first priority HPR among write requests, and a request assigned to the second priority LPR among the write requests. For example, classified requests could be added or inserted into different queues. Internal resources could be sequentially allocated to the read requests and the write requests included in the queues.

Referring to FIG. 2, the number of requests assigned to the first priority HPR among the read requests is greater than the number of requests assigned to the second priority LPR among the read requests, and the allocation ratio is set so that more resources are allocated to the requests with the first priority HPR. Accordingly, among a read credit (RD credit) that can be allocated for the read requests, the priority processor 212 can allocate entries of the read buffer to requests with the first and second priorities HPR, LPR (Used credit). An allowable amount of the read buffer can be used by the scheduler 214. There may be no difficulty in sequentially processing read requests with different priorities HPR, LPR in the read buffer.

However, while there may be no requests (Empty) with the first priority HPR among the write requests, the requests with the second priority LPR among the write requests can fill a queue of the write buffer. In this case, many internal resources allocated for the first priority (HPR) in the write buffer might not be used. On the other hand, because the internal resources allocated for the second priority (LPR) in the write buffer are not sufficient, there might be a delay in processing the write requests with the second priority (LPR) which are full in the queue, so that the overall processing could be delayed (Stall).

A large number of credits (WR credits) that can be allocated for the write requests might not be allocated or used by the priority processor 212, and thus the amount of allocated credits (Used credits) might become very small. Accordingly, the usage of the write buffer in the scheduler 214 could be reduced (Starvation). In this case, the scheduler 214 can only transmit the read command RD that should be processed first to the memory device, and a mode transition (e.g., from the read mode to the write mode) might not occur. Thus, the processing of the requests assigned the second priority LPR among the write requests might be continuously delayed, so that this operations can deteriorate the data input/output performance or operational safety of the memory system.

In a procedure in which the priority processor 212 handles the data I/O requests according to the type of the data I/O requests and the priorities assigned to the data I/O requests, a criterion for allocating internal resources can be fixed as described in FIG. 2. As described in FIG. 2, the data I/O request input to the priority processor 212 can be concentrated on a specific request with a low priority, and the memory system might not be able to efficiently use the internal resources, and the data I/O performance of the memory system could deteriorate.

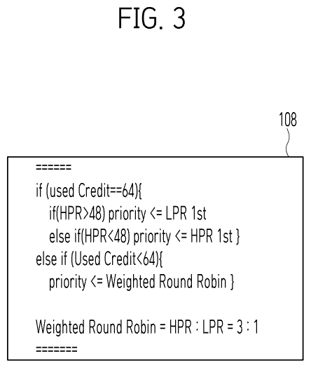

FIG. 3 illustrates a method for allocating resources based on priorities in a memory system according to an embodiment of the present disclosure. FIG. 3 illustrates a pseudo code for a resource allocation method according to priority of a memory system. According to an embodiment, the resource allocation method according to priority of the memory system described in FIG. 3 can be performed through the credit controller 108 described in FIG. 1 or the priority processor 212 described in FIG. 2.

Referring to FIG. 3, the resource allocation method according to priority can compare the number of data I/O requests to which internal resources have been allocated for processing (Used Credit) with the first reference value (e.g., 64). If the number of data I/O requests to which internal resources have been allocated for processing is equal to the first reference value (Used Credit==64), all internal resources are allocated and used, so there is no problem in terms of efficiency in resource usage within the memory system. In this case, the internal resources can be allocated to a next data I/O request according to priority. To this end, according to an embodiment, a resource allocation method based on priorities can compare a second reference value (e.g., 48) based on the priorities with the number of data I/O requests of the first priority, in order to determine which of the next data I/O request, assigned with the first priority or the second priority, is to be processed first. Here, the second reference value (e.g., 48) can be determined based on the first reference value (e.g., 64) and the allocation ratio (e.g., 3:1).

For example, if the number of requests with the first priority is greater than 48 (i.e., HPR>48), the internal resources can be first allocated to a request with the second priority among the next data I/O commands (i.e., priority <=LPR 1st). If the number of requests with the first priority is less than 48 (i.e., HPR<48), the internal resources can be first allocated to a request with the first priority among the next data I/O commands (i.e., priority <=HPR 1st). In this scheme, the allocation ratio of internal resources to a request with the first priority and a request with the second priority could be maintained at the preset ratio of 3:1.

If the number of data I/O requests to which internal resources are allocated is less than the first reference value (i.e., Used Credit <64), it can indicate that not all internal resources in the memory system have been allocated, and at least some internal resources might not be used. In this case, the allocation ratio might not be maintained, and the internal resources could be allocated to the next data I/O request in a weighted round robin manner that applies a weight instead of the allocation ratio. At this time, the weight could be set to 3:1, the same as the allocation ratio. Even if the weight is same to the allocation ratio, an allocation result could be different because the internal resource can be allocated to a next data I/O request of a type or a priority when there is no other type or priority request to be processed (e.g., NO stall). However, when the internal resources are allocated to the next data I/O request in the weighted round robin manner, the efficiency of internal resource usage could be increased even when specific type requests and specific priority requests described in FIG. 2 are intensively input. In addition, the usage of internal resources could be dynamically or adaptively changed according to the operating environment of the memory system through this scheme.

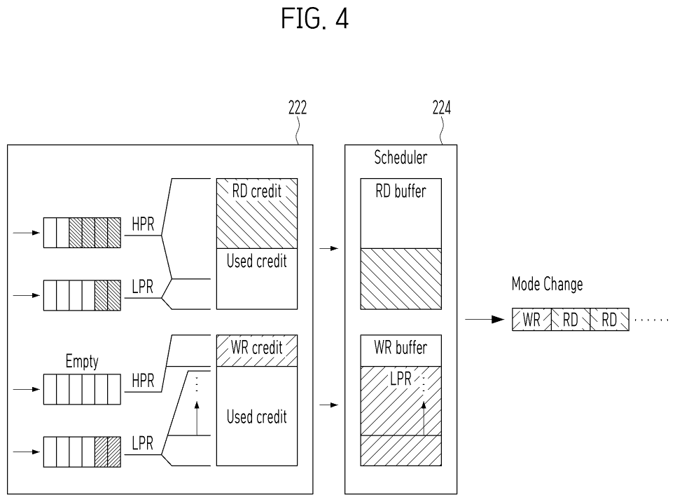

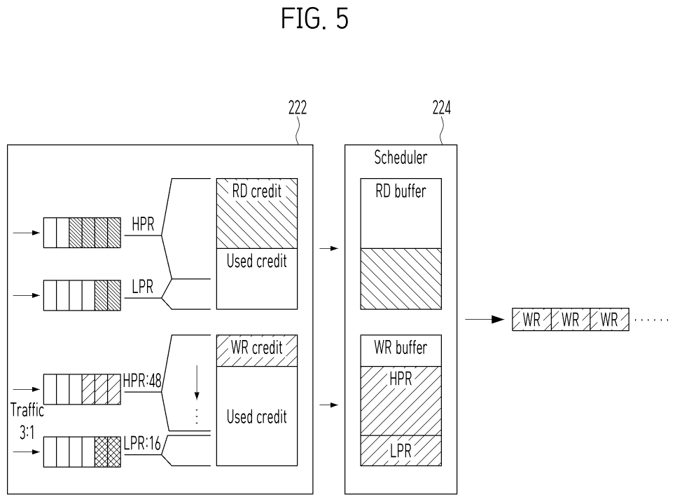

Hereinafter, with reference to FIGS. 4 and 5, the specific operation and effect of the resource allocation method according to the priority of the memory system described in FIG. 3 will be specifically described. FIG. 4 illustrates a second operation performed in a memory system according to an embodiment of the present disclosure. FIG. 5 illustrates a third operation performed in a memory system according to an embodiment of the present disclosure.

Referring to FIGS. 4 and 5, the memory system can include a priority processor 222 and a scheduler 224. The priority processor 222 can allocate the internal resources to process data I/O requests based on different priorities. The scheduler 224 can process data I/O requests to which internal resources are allocated. According to an embodiment, the priority processor 222 and the scheduler 224 can be included in the credit controller 108 or the hazard control unit (HCU) 110 described in FIG. 1.

Referring to FIGS. 2 and 4, there are no first requests with the first priority HPR among the write requests (Empty). But second requests with the second priority LPR among the write requests can fill the queue in the write buffer. The memory system can process or handle a second write request with the second priority LPR more quickly by applying the resource allocation method based on priorities of the memory system described in FIG. 3.

Because there are no requests with the first priority HPR among the write requests, the number of data I/O requests to which internal resources are allocated in the write buffer can be less than the first reference value (i.e., Used Credit <64). Accordingly, second write requests with the second priority LPR can be sequentially stored in the write buffer in the weighted round robin manner. That is, if there are no requests assigned to the first priority HPR among the write requests, the internal resources could be additionally allocated to the second write requests with the second priority LPR beyond the allocation ratio of 3:1. When adding a next write request to the write buffer according to the weighted round robin manner, second write requests with the second priority LPR can continue to be added to the write buffer because the write buffer includes no requests with the first priority HPR among the write requests. This scheme can increase the number of write requests to which the internal resources are allocated (i.e., increase the allocated credit (Used Credit)). Thus, this scheme can effectively increase the usage of the write buffer.

The scheduler 224 can check that both the read buffer where the read request is stored and the write buffer where the write request is stored can include data I/O requests to be processed or handled. The scheduler 224 can change the operation mode (e.g., read or write mode) to transmit the write request WR or the read request RD to the memory device. Through this, the memory system can sequentially process a next data I/O request even in an operating environment where data I/O requests with a specific type and a specific priority are intensively input.

Referring to FIG. 5, when a next data I/O request with the first priority HPR among plural write requests is input, the memory system can dynamically or adaptively change the usage of internal resources such as the write buffer. Because the number of data I/O requests to which internal resources are allocated in the write buffer is less than the first reference value (i.e., Used Credit <64), the internal resources can be allocated to the next data input/output request in the weighted round robin manner. At this time, because the weight is the same as the allocation ratio, first write requests with the first priority HPR stored in the write buffer could increase by three times, as compared to second write requests with the second priority LPR, when the numbers of the first and second write requests are sufficient. Therefore, as the usage rate of the write buffer increases, the ratio of the write requests with the first priority HPR can rapidly increase. This increasement can continue until the number of data I/O requests to which internal resources are allocated becomes equal to the first reference value (i.e., Used Credit==64).

The scheduler 224 can check that the number of data I/O requests to be processed or handled in the write buffer where the write requests are stored is rapidly increasing. Then, the scheduler 224 can continuously transmit the write request WR with the first priority HPR to the memory device. Through this operation, the memory system can advance a processing order for the write request with the first priority HPR (e.g., the write request input from the external device).

As described above, the resource allocation method based on the priority in the memory system can maintain the allocation ratio based on the priorities or maintain policies for allocation and processing of internal resources based on the priorities. In addition, the memory system can use the weighted round robin method that applies the same weight as the allocation ratio to improve a processing rate based on the allocation ratio even for the concentration phenomenon of data I/O requests of a specific type or a specific priority.

FIG. 6 illustrates a data processing apparatus 400 according to an embodiment of the present disclosure.

Referring to FIG. 6, the data processing apparatus 400 can be implemented in the form of a multi-chip package including a plurality of semiconductor devices or a plurality of semiconductor chips. According to an embodiment, the data processing apparatus 400 can include an HBM module 410. The HBM module 410 can correspond to the memory system 100 described in FIG. 1.

The data processing apparatus 400 can include an interposer 406 disposed on a package substrate 408. The interposer 406 can provide a path for data communication between a plurality of devices or a plurality of components. The interposer 406 can be used to simplify the manufacturing process of a multi-chip package for supporting high-speed data communication and to improve signal quality in high-speed data communication. The HBM module 410 disposed on the interposer 406 can include a plurality of memory dies 414A to 414D and a logic die 412. The HBM module 410 described in FIG. 6 can include four memory dies 414A to 414D, but the number of memory dies can be 8, 12, 16, or etc., depending on required performance included in the HBM module 410. According to an embodiment, each of the memory dies 414A to 414D can include a data storage area including volatile memory cells (e.g., DRAM, SRAM, or etc.). According to an embodiment, the plurality of memory dies 414A to 414D can include a data storage area including memory cells of different types (e.g., volatile memory cells and non-volatile memory cells). For example, some of the plurality of memory dies 414A to 414D can be a DRAM memory die, and others may be a NAND memory die.

The plurality of memory dies 414A to 414D can be vertically stacked and can correspond to the plurality of memory devices 114A to 114H described in FIG. 1. The plurality of memory dies 414A to 414D can transmit and receive data or signals through Through-Silicon Vias (TSVs) for vertical electrical connection between the memory dies. In addition, each of the plurality of memory dies 414A to 414D can include a micro bump to maintain a gap with the adjacent die and ensure electrical contact.

A host 402 connected to the HBM module 410 and configured to process data can be placed on the interposer 406. The host 402 can include a central processing unit (CPU), a graphics processing unit (GPU), or a System-on-a-Chip (SoC). The host 402 can correspond to the external device connected to the memory system 100 described in FIG. 1. According to an embodiment, the HBM module 410 can be directly connected to the host 402, such as a CPU or a GPU, and can increase bandwidth to bypass the memory controller. This structure might reduce data transmission delay time and improve system performance. For example, the host 402, such as a CPU or a GPU, can send a data read/write request to the HBM module 410, and the HBM controller included in the logic die 412 can analyze a request input from the host 402 and transmit the request to a specific memory bank included in the plurality of memory dies 414A to 414D. The specific memory bank included in the plurality of memory dies 414A to 414D can read or write data requested through the TSV and transmit read data to the host 402, such as a CPU or a GPU, through the interposer 406. In addition, the host 402, such as a CPU or GPU, can process data output from the HBM module 410 and return a result (e.g., data) to the HBM module 410.

According to the embodiment, the HBM controller included in the logic die 412 can include the credit controller 108 and the hazard control unit 110 described in FIG. 1. The HBM controller included in the logic die 412 can efficiently control the memory banks included in the plurality of memory dies 414A to 414D and manage data transfer based on the priorities assigned to the plurality of data input/output requests.

Further, the logic die 412 and the host 402 can include at least one component corresponding to a physical layer PHY which is responsible for transmitting and receiving data or signals therebetween.

FIG. 7 illustrates another data processing apparatus according to an embodiment of the present disclosure.

Referring to FIG. 7, the data processing apparatus may include a host 302 and a memory system (e.g., compute express link (CXL™) device) 310. The host 302 and the memory system 310 can perform data communication via a computer-memory link-based (e.g., CXL™) protocol or interface. A controller 312 within the memory system 310 can include a credit controller 108, a hazard control unit 110, and a memory controller 112 as described in FIG. 7. The controller 312 can manage and control data I/O operations performed in a memory device (or a CXL™ memory device) 314 based on priorities assigned to plural data I/O requests.

The memory system 310 can be designed to support memory-centric computing technology. The memory-centric computing technology can provide a dynamically scalable shared memory that overcomes the limitations of large-capacity data processing performance and capacity occurring in one type of CPU-centric systems that have been proposed, in line with demands or requirements for a memory disaggregation system. Thus, the system scale can be flexibly maintained in line with requirements regarding the data processing apparatus. Due to the explosive increase in amounts of data from emerging applications such as big data and artificial intelligence (AI), the data processing apparatus including at least one computing device can be designed or built to satisfy large-capacity, high-bandwidth memory, or innovative architectural changes. The number of servers and memory devices can continue to increase to meet overwhelming memory requirements. The computer-memory link-based protocol or computer-memory link-based interface can be provided to support large-capacity and high-bandwidth memory.

Memory disaggregation can be an architectural solution that separates a memory (e.g., a memory device) from a compute node (e.g., a computing device), allowing a system designer to flexibly expand additional memory capacity independently of each computing server while meeting the memory requirements of user applications. For example, a computing server with high memory usage can use a memory device located farther away from other nodes included in a disaggregated group. Accordingly, this disaggregation scheme can manage or use resources more efficiently than one type of dedicated CPU and memory architectures that have been proposed.

The computer-memory link (e.g., Compute Express Link, CXL™) can be provided to accelerate architectural transition to memory disaggregation. The computer-memory link is an industry-supported cache-coherent interconnect (CCI) for various processors to efficiently expand memory capacity through a memory semantic protocol. Unlike a host memory 306 that is entirely dependent on a host central processing unit (e.g., CPU) 304, a memory device 314 connected via the CXL-based protocol or CXL-based interface to the host 302 can include additional data or values such as data processing engines through handshaking communication, as a memory.

The host 302 can include the host CPU 304 and the host memory 306. The numbers and configurations of the host CPU 304 and the host memory 306 can vary depending on the performance, operating requirements, operating speed, and data I/O speed of the host 302. The host CPU 304 and the host memory 306 can transmit and receive data through a communication interface protocol mutually agreed upon with each other. There are various communication standards or interfaces such as Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe), Serial-attached SCSI (SAS), Serial Advanced Technology Attachment (SATA), and Mobile Industry Processor Interface (MIPI), as examples of agreed upon standards for transmitting and receiving data. According to an embodiment, the host 302 and the host memory 306 can be coupled via a Universal Serial Bus (USB). The Universal Serial Bus (USB) can include an expandable, hot-pluggable plug-and-play serial interface that ensures an economical standard connection to peripheral devices such as a keyboard, mouse, joystick, printer, scanner, storage device, modem, video conferencing camera, etc.

In FIG. 7, the host 302 can perform data communication with the memory system 310 through the computer-memory link-based protocol or interface (e.g., CXL™ protocol or CXL™ interface). CXL™ (Compute Express Link) and PCIe (Peripheral Component Interconnect Express) are both standard interfaces for connecting peripherals and CPUs in a computer system. However, there are differences in several aspects between the CXL™ and the PCIe. First, the PCIe is designed as a standard for general input/output devices, while the CXL™ is an interface specialized for memory access and high-speed data transmission in a high-performance computing environment. Thus, the CXL™ is designed so that the CPU can directly access the memory of the device, while the PCIe may have limited such functions. In addition, while the PCIe uses a unidirectional communication way, the CXL™ can support bidirectional communication. For example, the CXL™ devices can support to send and receive data simultaneously. Because the CXL™ is designed to maintain backward compatibility with the PCIe, the CXL™ device could be designed or implemented by utilizing one type of PCIe infrastructure that has been proposed.

According to an embodiment, data communication of the memory device 314 (e.g., a CXL™ memory device) distributed to the host central processing unit (e.g. CPU) 304 may have a limited interface bandwidth, as compared to that of the host memory 306. For example, in cases of DDR4 DIMM and DDR5 DIMM used as the host memory 306, the DIMM has 64-bit (i.e., 8-byte) data width. The maximum bandwidth could be 2.56 GB/s (=3.2 Gbps×8 bytes) for DDR4 and 38.4 GB/s (=4.8 Gbps×8 bytes) or 51.2 GB/s (=6.4 Gbps×8 bytes) for DDR5. Accordingly, the interface bandwidth may be 0.4^{s-1} (=25.6 GB/s/64 GB) and 0.6^{s-1} (=38.4 GB/s/64 GB) or 0.8^{s-1} (=51.2 GB/s/64 GB) when a storage capacity of each chip is 64 Gb. On the other hand, the interface bandwidth of the memory system 310 may be very limited to 0.0625^{s-1} (=32 GB/s(@PCIe5.0×8)/512 GB). This bandwidth difference can limit the input/output performance of the data processing apparatus.

To overcome above-described issues, the memory system 310 may include a controller 312 (e.g., a CXL™ core) designed and used for near data processing (NDP) (or near-distance data processing). The near data processing (NDP) can be a computing scheme for improving or enhancing the efficiency of data processing. The near data processing (NDP) could be based on a configuration in which the controller 312 (e.g., at least one processor or core that processes data) is arranged or located close to a data storage or memory such as the memory device 314.

In one type of computing model that has been proposed, the host CPU 304 would retrieve data from the memory device 314 coupled to expand the host memory 306, process the data, and store results back in the memory device 314. However, in applications that require processing a large amount of data, that scheme could cause a bandwidth bottleneck between the memory device 314 and the host CPU 304. To solve this issue, the near data processing (NDP) can be designed to place the controller 312 (e.g., a processor that processes data) close to the memory device 314 in which the processed data is stored. That is, instead of moving data from the memory device 314 to the host CPU 304, the controller 312, which is the processor that performs data processing, can be included in the memory system 310 which is the location of the data. This configuration can significantly reduce or avoid delay time and energy consumption due to data movement.

Unlike the memory system 310, the host memory 306 can be used for in-memory processing of the host CPU 304. In-memory processing can store as much data as possible in the host memory 306 and reduce the delay time due to disk I/O (e.g., I/O of the memory system). The host memory 306 under this scheme could support great performance in database work, real-time analysis, etc. However, because the host memory 306 is expensive and has limited capacity, there may be limitations in processing very large data sets. Thus, the data processing apparatus can overcome some limitations of operation and performance of the host memory 306 through the memory system 310 including the controller 312 for the near data processing (NDP).

As above described, a memory system according to an embodiment of the present disclosure can dynamically and adaptively determine scheduling of data input/output requests according to priorities. Accordingly, even if a difference between the number of data input/output requests with a first priority and the number of data input/output requests with a second priority increases, the difference could be reduced quickly while processing or handling operations corresponding to data input/output requests based on the scheduling determined based on the priorities. Through this, the memory system can more efficiently use resources for processing.

In addition, the memory system according to an embodiment of the present disclosure can increase usage rate of limited internal resources by adaptively inducing changes in resource allocation according to changes in the operating environment without changing a policy for allocating resources based on priorities regarding data input/output requests.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods or operations of the computer, processor, controller, or other signal processing device, are described in detail, the code or instructions for implementing the operations of the method embodiments may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, generators, logic, interfaces, decoders, drivers, and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, generators, logic, interfaces, decoders, drivers, and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, generators, logic, interfaces, decoders, drivers, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods or operations of the computer, processor, microprocessor, controller, or other signal processing device, are described in detail, the code or instructions for implementing the operations of the method embodiments may transform the computer, processor, controller, or other signal processing device into a special-purpose processor for performing the methods described herein.

While the invention has been illustrated and described with respect to the specific embodiments, it will be apparent to those skilled in the art in light of the present disclosure that various changes and modifications may be made without departing from the spirit and scope of the present disclosure as defined in the following claims. Furthermore, the embodiments may be combined to form additional embodiments.

What is claimed is:

1. A memory system comprising:
at least one memory device; and
a controller coupled to the at least one memory device and configured to change a processing order of next data input/output (I/O) requests input after plural data I/O requests, based on whether preset internal resources are allocated for processing the plural data I/O requests.

2. The memory system according to claim 1, wherein the controller is configured to:
determine, when the preset internal resources are allocated for processing the plural data I/O requests, the processing order of the next data I/O requests based on an allocation ratio of the internal resources according to priorities; and
determine, when at least some of the preset internal resources is not allocated for processing the plural data I/O requests, the processing order of the next data I/O requests in a round robin manner with the allocation ratio of the internal resources.

3. The memory system according to claim 2, wherein the controller is further configured to compare a number of the plural data I/O requests with a first reference value corresponding to the internal resources to determine whether the preset internal resources are allocated.

4. The memory system according to claim 3, wherein the internal resources comprise a read buffer and a write buffer included in the controller, or operatively engaged with the controller,
wherein each of the read buffer and the write buffer is configured to store a maximum number of the plural data I/O requests, the maximum number corresponding to the first reference value.

5. The memory system according to claim 4, wherein the controller is configured to:
receive read data from the at least one memory device or receive a completion signal for write data from the at least one memory device, in response to the data I/O requests stored in each of the read buffer and the write buffer; and
remove a first data input/output request from the read buffer or the write buffer when a response to the first data input/output request corresponding to the read data or the completion signal is generated.

6. The memory system according to claim 4, wherein the priorities comprises a first priority and a second priority lower than the first priority,
wherein the controller is configured to store, in the read buffer or the write buffer, at least one first data I/O request of the first priority and at least one second data input/output request of the second priority, and
wherein a first number of the at least one first I/O request and a second number of the at least one second I/O request, which are stored in the read buffer or the write buffer, are determined based on the allocation ratio.

7. The memory system according to claim 6, wherein the first number is equal to or less than three times the second number.

8. The memory system according to claim 6, wherein the controller is configured to:
compare the first number with a second reference value based on the priorities when the preset internal resources are allocated; and
determine priorities for the next data I/O requests to be stored in the read buffer or the write buffer based on a comparison result.

9. The memory system according to claim 8, wherein the second reference value is determined based on the allocation ratio.

10. The memory system according to claim 9, wherein the second reference value is ¾ of the first reference value.

11. A controller configured to allocate internal resources for processing plural data input/output (I/O) requests to be performed within at least one memory device, wherein the controller is configured to:
determine, when preset internal resources are allocated for processing the plural data I/O requests, a processing order of next data I/O requests input after the plural data I/O requests, based on an allocation ratio of the internal resources according to a priorities; and
determine, when at least some of the preset internal resources is not allocated for processing the plural data I/O requests, the processing order of the next data I/O requests in a round robin manner with the allocation ratio.

12. The controller according to claim 11, wherein the controller is further configured to compare a number of the plural data I/O requests with a first reference value corresponding to the internal resources to determine whether the preset internal resources are allocated.

13. The controller according to claim 12, wherein the internal resources comprise a read buffer and a write buffer included in the controller, or operatively engaged with the controller,
wherein each of the read buffer and the write buffer is configured to store a maximum number of the plural data I/O requests, the maximum number corresponding to the first reference value.

14. The controller according to claim 13, wherein the controller is configured to:
receive read data from the at least one memory device or receive a completion signal for write data from the at least one memory device in response to the data I/O requests stored in each of the read buffer and the write buffer; and
remove a first data input/output request from the read buffer or the write buffer when a response to the first data input/output request corresponding to the read data or the completion signal is generated.

15. The controller according to claim 13, wherein the priorities comprises a first priority and a second priority lower than the first priority,
wherein the controller is configured to store, in the read buffer or the write buffer, at least one first data I/O request of the first priority and at least one second data input/output request of the second priority, and
wherein a first number of the at least one first I/O request and a second number of the at least one second I/O request, which are stored in the read buffer or the write buffer, are determined based on the allocation ratio.

16. The controller according to claim 15, wherein the controller is configured to:
compare the first number with a second reference value based on the priorities when the preset internal resources are allocated; and
determine priorities for the next data I/O requests to be stored in the read buffer or the write buffer based on a comparison result.

17. A method for operating a memory system, the method comprising:
assigning different priorities to plural data input/output (I/O) requests based on properties of the plural data I/O requests to be performed within at least one memory device;
allocating internal resources for processing the plural data I/O requests based on an allocation ratio corresponding to the priorities; and
changing a processing order of next data I/O requests input after the plural data I/O requests, based on whether preset internal resources are allocated.

18. The method according to claim 17, wherein changing the processing order comprises:
determining, when the preset internal resources are allocated for processing the plural data I/O requests, the processing order of the next data I/O requests based on an allocation ratio of the internal resources according to priorities; and
determining, when at least some of the preset internal resources is not allocated for processing the plural data I/O requests, the processing order of the next data I/O requests in a round robin manner with the allocation ratio.

19. The method according to claim 18, further comprising comparing a number of the plural data I/O requests with a first reference value corresponding to the internal resources to determine whether the preset internal resources are allocated.

20. The method according to claim 19, wherein the internal resources comprise a read buffer and a write buffer included in the controller, or operatively engaged with the controller,
wherein each of the read buffer and the write buffer is configured to store a maximum number of the plural data I/O requests, the maximum number corresponding to the first reference value.
